(19) United States
(12) Patent Application Publication
(10) Pub. No.: US 2025/0287616 A1
(43) Pub. Date: Sep. 11, 2025

(54) SEMICONDUCTOR STRUCTURE AND MANUFACTURING METHOD THEREOF

(71) Applicant: Winbond Electronics Corp., Taichung City (TW)

(72) Inventors: Li-Min Yan, Tainan (TW); Pin-Hung Chen, Tainan (TW); Ji-Min Lin, Tainan (TW)

(73) Assignee: Winbond Electronics Corp., Taichung City (TW)

(21) Appl. No.: 19/026,183

(22) Filed: Jan. 16, 2025

(30) Foreign Application Priority Data
Mar. 6, 2024 (TW) 113108223

(51) Int. Cl. H10D 1/00; H10B 12/00; H10D 1/68; H10D 80/20

(52) U.S. Cl. CPC H10D 1/042; H10D 1/714; H10D 1/716; H10D 80/215; H10B 12/033; H10B 12/30

(57) ABSTRACT

A semiconductor structure including a substrate and a capacitor is provided. The capacitor is located on the substrate. The capacitor includes a first electrode, a second electrode, a first dielectric layer, and a second dielectric layer. The first electrode is located on the substrate. The first electrode has a first surface and a second surface opposite to each other. The second electrode is located on the first electrode. The first dielectric layer is located between the first surface and the second electrode. The second dielectric layer is located between the first dielectric layer and the second electrode and between the second surface and the second electrode.

### CROSS-REFERENCE TO RELATED APPLICATION

This application claims the priority benefit of Taiwan application serial no. 113108223, filed on Mar. 6, 2024. The entirety of the above-mentioned patent application is hereby incorporated by reference herein and made a part of this specification.

### BACKGROUND

### Technical Field

The disclosure relates to a semiconductor structure and a manufacturing method thereof, and more particularly, to a semiconductor structure including a capacitor and a manufacturing method thereof.

### Description of Related Art

In a semiconductor structure (e.g., a dynamic random access memory (DRAM) structure) including a capacitor, when the capacitor bends or collapses, reliability of the semiconductor structure will be reduced. Therefore, how to improve the reliability of the semiconductor structure is a goal to work on.

### SUMMARY

The disclosure provides a semiconductor structure and a manufacturing method thereof, which may improve reliability of the semiconductor structure.

The disclosure provides a semiconductor structure, including a substrate and a capacitor. The capacitor is located on the substrate. The capacitor includes a first electrode, a second electrode, a first dielectric layer, and a second dielectric layer. The first electrode is located on the substrate. The first electrode has a first surface and a second surface opposite to each other. The second electrode is located on the first electrode. The first dielectric layer is located between the first surface and the second electrode. The second dielectric layer is located between the first dielectric layer and the second electrode and between the second surface and the second electrode.

The disclosure provides a manufacturing method of a semiconductor structure, including the following. A substrate is provided. A capacitor is formed on the substrate. The capacitor includes a first electrode, a second electrode, a first dielectric layer, and a second dielectric layer. The first electrode is located on the substrate. The first electrode has a first surface and a second surface opposite to each other. The second electrode is located on the first electrode. The first dielectric layer is located between the first surface and the second electrode. The second dielectric layer is located between the first dielectric layer and the second electrode and between the second surface and the second electrode.

Based on the above, in the semiconductor structure and the manufacturing method thereof provided in the disclosure, the first dielectric layer is located between the first surface of the first electrode and the second electrode, and the second dielectric layer is located between the first dielectric layer and the second electrode and between the second surface of the first electrode and the second electrode. That is, the first dielectric layer and the second dielectric layer are provided on the first surface of the first electrode. In this way, the capacitor may be prevented from bending or collapsing, thereby improving the structural strength of the capacitor and the reliability of the semiconductor structure. In addition, the first dielectric layer may balance a thickness of capacitance dielectric layers (including the first dielectric layer and the second dielectric layer) located on the first surface (e.g., an inner surface) of the first electrode and the second surface (e.g., an outer surface) of the first electrode. In addition, the first dielectric layer may improve step coverage capability of the capacitance dielectric layers (including the first dielectric layer and the second dielectric layer) located on the first surface (e.g., the inner surface) of the first electrode.

In order for the aforementioned features and advantages of the disclosure to be more comprehensible, embodiments accompanied with drawings are described in detail below.

### BRIEF DESCRIPTION OF THE DRAWINGS

FIGS. 1A to 1G are cross-sectional views of a manufacturing process of a semiconductor structure according to some embodiments of the disclosure.

FIG. 2 is a top view of a capacitor in FIG. 1G.

### DETAILED DESCRIPTION OF DISCLOSED EMBODIMENTS

The embodiments are described in detail below with reference to the accompanying drawings, but the provided embodiments are not intended to limit the scope of the disclosure. For ease of understanding, the same elements in the following description will be denoted by the same reference numerals. In addition, the drawings are drawn only for the purpose of description, and are not drawn according to original sizes. Furthermore, the features in the top view and the features in the cross-sectional view are not drawn to the same scale. In fact, the dimensions of the various features may be arbitrarily increased or reduced for clarity of discussion.

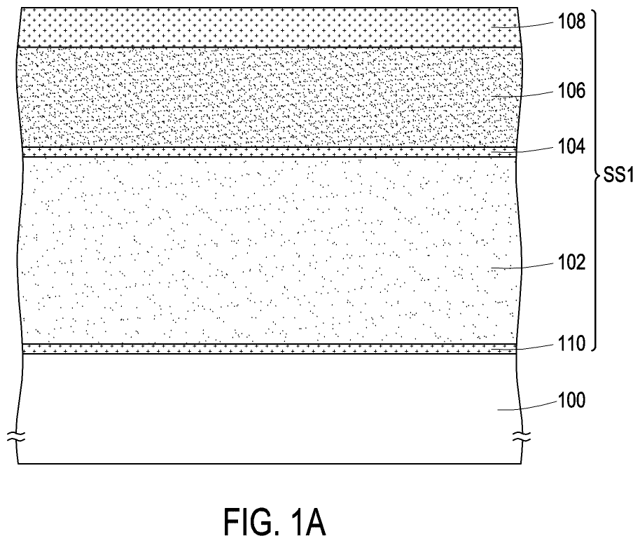

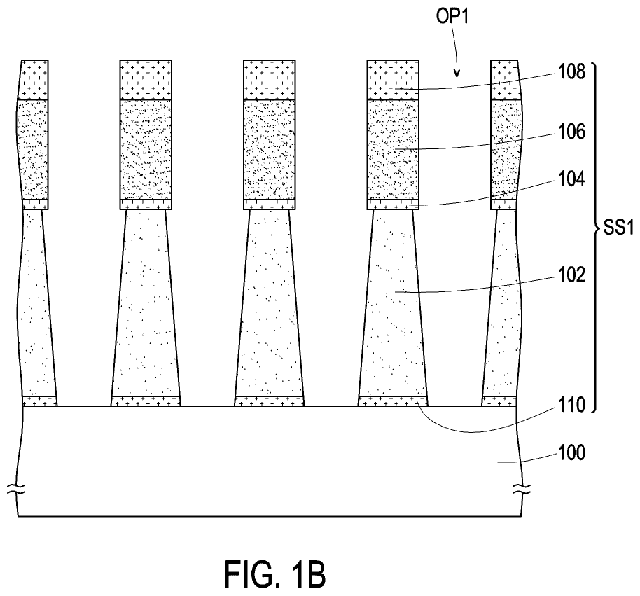

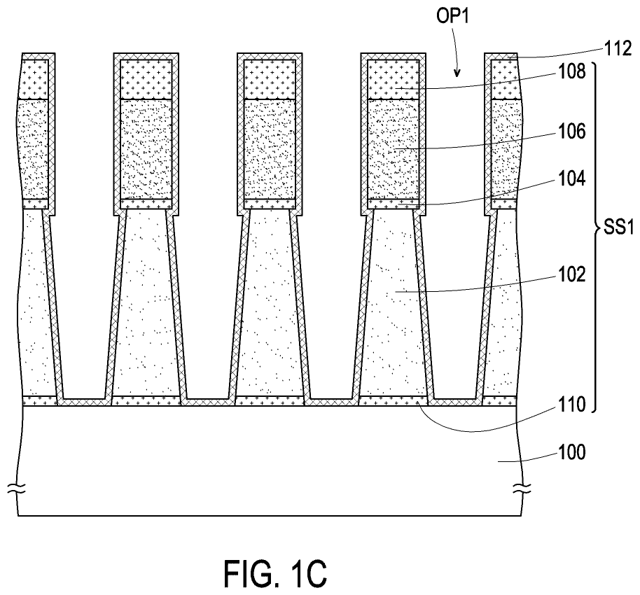

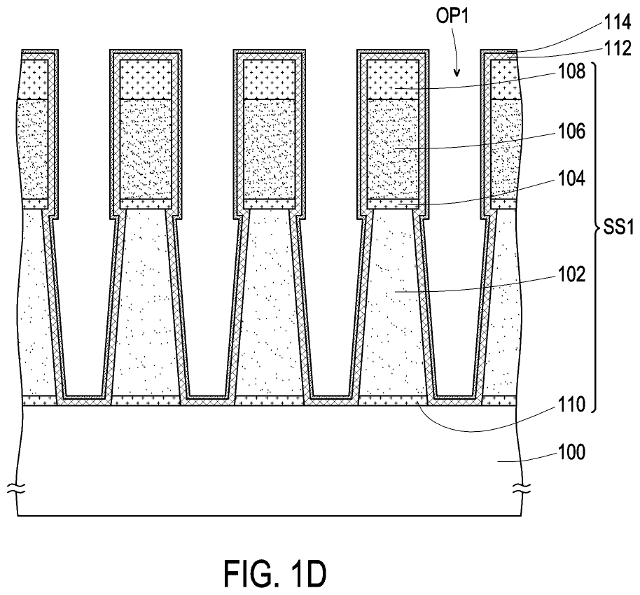

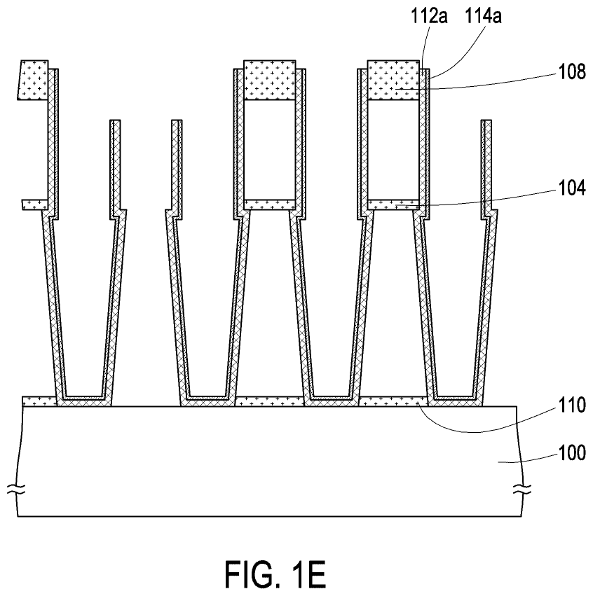

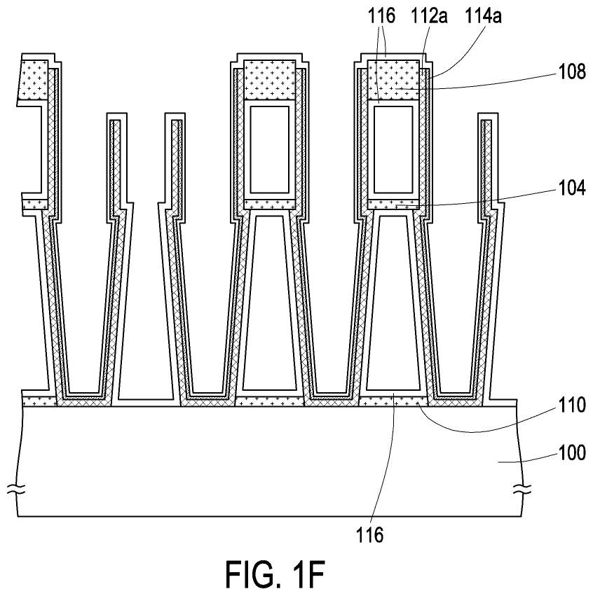

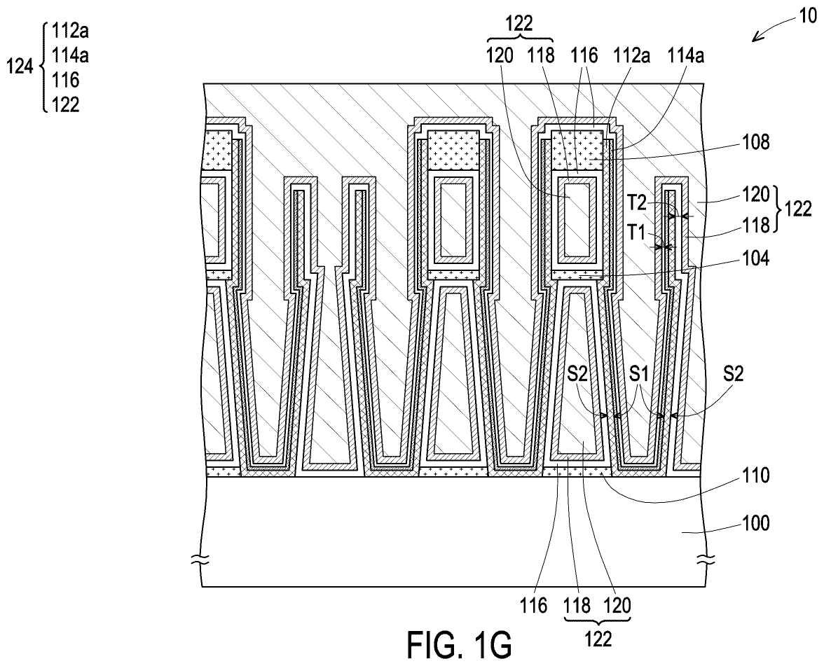

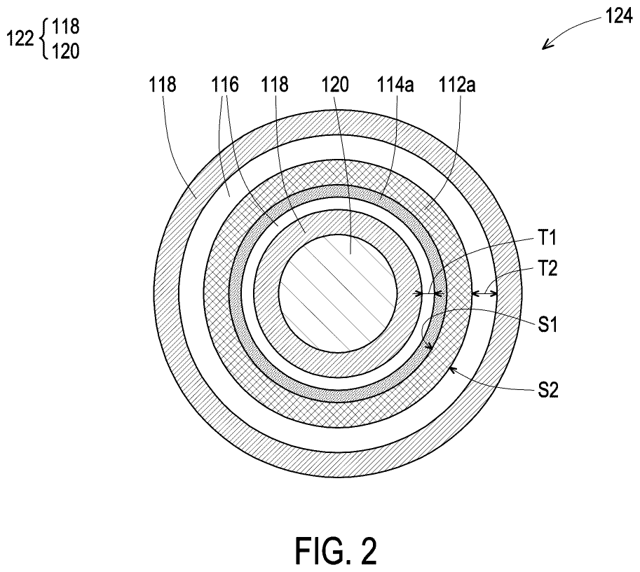

FIGS. 1A to 1G are cross-sectional views of a manufacturing process of a semiconductor structure according to some embodiments of the disclosure. FIG. 2 is a top view of a capacitor in FIG. 1G. In addition, in FIG. 2, some components in FIG. 1G are omitted to clearly describe a configuration relationship between the components in FIG. 2.

Referring to FIG. 1A, a substrate 100 is provided. The substrate 100 may be a semiconductor substrate, such as a silicon substrate. In addition, although not shown in the drawing, there may be corresponding components on and/or in the substrate 100 depending on a type of the semiconductor structure. For example, the substrate 100 may have required components (not shown) such as isolation structures, doping regions, and/or buried word lines, and the substrate 100 may have required components (not shown) such as dielectric layers and/or interconnection structures (e.g., bit lines and contact windows). Here, descriptions thereof are omitted.

Next, a stack structure SS1 may be formed on the substrate 100. The stack structure SS1 may include a dielectric layer 102, a support layer 104, a dielectric layer 106, and a support layer 108. The dielectric layer 102 is located on the substrate 100. In some embodiments, a material of the dielectric layer 102 is, for example, oxides (e.g., silicon oxide). The support layer 104 is located on the dielectric layer 102. In some embodiments, a material of the support layer 104 is, for example, nitrides (e.g., silicon nitride). The dielectric layer 106 is located on the support layer 104. In some embodiments, a material of the dielectric layer 106 is, for example, oxides (e.g., silicon oxide). The support layer 108 is located on the dielectric layer 106. In some embodiments, a material of the support layer 108 is, for example, nitrides (e.g., silicon nitride). In some embodiments, the stack structure SS1 may further include a stop layer 110. The stop layer 110 is located between the dielectric layer 102 and the substrate 100. In some embodiments, a material of the stop layer 110 is, for example, nitrides (e.g., silicon nitride).

Referring to FIG. 1B, an opening OP1 may be formed in the stack structure SS1. The opening OP1 may penetrate the support layer 108, the dielectric layer 106, the support layer 104, the dielectric layer 102, and the stop layer 110. In some embodiments, a patterning process may be performed on the stack structure SS1 to form the opening OP1 in the stack structure SS1. The patterning process may include a photolithography process and an etching process.

Referring to FIG. 1C, an electrode material layer 112 may be formed conformally on the stack structure SS1 and in the opening OP1. In some embodiments, a material of the electrode material layer 112 is, for example, titanium nitride. In some embodiments, a method of forming the electrode material layer 112 is, for example, chemical vapor deposition.

Referring to FIG. 1D, a dielectric material layer 114 may be formed conformally on the electrode material layer 112. In some embodiments, a material of the dielectric material layer 114 is, for example, a high dielectric constant material. In some embodiments, a material of the dielectric material layer 114 is, for example, hafnium oxide (HfO), zirconium oxide (ZrO), or niobium oxide (NbO). In some embodiments, a method of forming the dielectric material layer 114 is, for example, atomic layer deposition.

Referring to FIG. 1E, the patterning process may be performed on the dielectric material layer 114 and the electrode material layer 112 to form a dielectric layer 114a and an electrode 112a. In some embodiments, the etching process (e.g., a dry etching process) may be performed on the dielectric material layer 114 and the electrode material layer 112 by using a patterned mask layer (e.g., a patterned photoresist layer and/or a patterned hard mask layer) (not shown) as a mask to form the dielectric layer 114a and the electrode 112a, and expose a portion of the support layer 108.

In addition, a portion of the support layer 108 may be removed to expose a portion of the dielectric layer 106. In some embodiments, a method of removing a portion of the support layer 108 is, for example, dry etching. Then, the dielectric layer 106 may be removed to expose the support layer 104. In some embodiments, a method of removing the dielectric layer 106 is, for example, wet etching. Next, a portion of the support layer 104 may be removed to expose a portion of the dielectric layer 102. In some embodiments, a method of removing a portion of the support layer 104 is, for example, dry etching. Then, the dielectric layer 102 may be removed. In some embodiments, a method of removing the dielectric layer 102 is, for example, wet etching.

Referring to FIG. 1F, after the dielectric layer 102 is removed, a dielectric layer 116 may be formed conformally on the electrode 112a, the dielectric layer 114a, the support layer 104, the support layer 108, and the stop layer 110. In some embodiments, a material of the dielectric layer 116 is, for example, the high dielectric constant material. In some embodiments, the material of the dielectric layer 116 is, for example, hafnium oxide, zirconium oxide, niobium oxide, or a composite material of zirconium oxide/aluminum oxide/zirconia (ZAZ). In some embodiments, a method of forming the dielectric layer 116 is, for example, atomic layer deposition or chemical vapor deposition.

Referring to FIG. 1G, an electrode layer 118 may be formed conformally on the dielectric layer 116. In some embodiments, a material of the electrode layer 118 is, for example, titanium nitride. In some embodiments, a method of forming the electrode layer 118 is, for example, chemical vapor deposition.

Then, an electrode layer 120 may be formed on the electrode layer 118. In this way, an electrode 122 may be formed. In this embodiment, the electrode 122 may include the electrode layer 118 and the electrode layer 120, but the disclosure is not limited thereto. The electrode layer 120 may be a single-layer structure or a multi-layer structure. In some embodiments, a material of the electrode layer 120 is, for example, doped silicon germanium (SiGe), tungsten, or a combination thereof. In some embodiments, a method of forming the electrode layer 120 is, for example, chemical vapor deposition.

Through the above method, a capacitor 124 may be formed on the substrate 100. Hereinafter, a semiconductor structure 10 in the above embodiment will be described with reference to FIGS. 1G and 2. In addition, although a method of forming the semiconductor structure 10 is described by taking the above method as an example, the disclosure is not limited thereto.

Referring to FIGS. 1G and 2, the semiconductor structure 10 includes the substrate 100 and the capacitor 124. In some embodiments, the semiconductor structure 10 may be a memory structure, such as a dynamic random access memory structure. In some embodiments, the capacitor 124 may be used as a capacitor in a dynamic random access memory.

The capacitor 124 is located on the substrate 100. The capacitor 124 includes the electrode 112a, the electrode 122, the dielectric layer 114a, and the dielectric layer 116. The electrode 112a is located on the substrate 100. In some embodiments, the electrode 112a may be used as a lower electrode of the capacitor 124. The electrode 112a has a surfaces S1 and a surface S2 opposite to each other. In some embodiments, a cross-sectional shape of the electrode 112a may include a U-shape. In a case where the cross-sectional shape of the electrode 112a includes the U-shape, the surface S1 may be an inner surface of the electrode 112a, and the surface S2 may be an outer surface of the electrode 112a.

The electrode 122 is located on the electrode 112a. In some embodiments, the electrode 122 may be used as an upper electrode of the capacitor 124. The electrode 122 may be a single-layer structure or a multi-layer structure. In this embodiment, the electrode 122 is a multi-layer structure as an example and includes the electrode layer 118 and the electrode layer 120, but the disclosure is not limited thereto. The electrode layer 118 is located on the electrode 112a. The electrode layer 120 is located on the electrode layer 118.

The dielectric layer 114a is located between the surface S1 and the electrode 122. The dielectric layer 114a may prevent the capacitor 124 from bending or collapsing, thereby improving structural strength of the capacitor 124 and reliability of the semiconductor structure 10. In some embodiments, the dielectric layer 114a may be in direct contact with the surface S1. A top-view shape of the dielectric layer 114a may be annular and may surround the electrode layer 120. In some embodiments, the dielectric layer 114a and the electrode 112a may not include the same metal element. In some embodiments, a material of the dielectric layer 114a is, for example, the high dielectric constant material, thereby increasing capacitance of the capacitor 124. In some embodiments, the material of the dielectric layer 114a is, for example, hafnium oxide, zirconium oxide, or niobium oxide. In some embodiments, the material of the dielectric layer 114a is, for example, a material with a dielectric constant greater than 20, such as hafnium oxide, zirconium oxide, niobium oxide, lanthanum oxide, or tantalum oxide. In some embodiments, the material of the dielectric layer 114a is, for example, a material with an energy gap greater than 8 electron volts, such as aluminum oxide.

The dielectric layer 116 is located between the dielectric layer 114a and the electrode 122 and between the surface S2 and the electrode 122. In some embodiments, the dielectric layer 114a may not be located between the surface S2 and the dielectric layer 116. In some embodiments, the dielectric layer 116 may be in direct contact with the surface S2. In some embodiments, the material of the dielectric layer 114a may be different from the material of the dielectric layer 116. In other embodiments, the material of the dielectric layer 114a may be the same as the material of the dielectric layer 116. In some embodiments, the material of the dielectric layer 116 is, for example, the high dielectric constant material, thereby increasing the capacitance of the capacitor 124. In some embodiments, the material of the dielectric layer 116 is, for example, hafnium oxide, zirconium oxide, niobium oxide, or the composite material of zirconium oxide/aluminum oxide/zirconia (ZAZ). In some embodiments, the material of the dielectric layer 116 is, for example, the material with the dielectric constant greater than 20, such as hafnium oxide, zirconium oxide, niobium oxide, lanthanum oxide, or tantalum oxide. In some embodiments, the material of the dielectric layer 116 is, for example, the material with the energy gap greater than 8 electron volts, such as aluminum oxide.

In some embodiments, a thickness T1 of the dielectric layer 116 located on the surface S1 (e.g., the inner surface) may be less than a thickness T2 of the dielectric layer 116 located on the surface S2 (e.g., the outer surface). Therefore, a thickness of capacitance dielectric layers (including the dielectric layer 114a and the dielectric layer 116) located on the surface S1 (e.g., the inner surface) and the surface S2 (e.g., the outer surface) may be balanced by the dielectric layer 114a.

The semiconductor structure 10 may further include the support layer 104 and the support layer 108. The support layer 104 is located on the surface S2 of the electrode 112a. The support layer 104 may be in direct contact with the electrode 112a. The support layer 108 is located on the surface S2 of the electrode 112a. The support layer 108 may be in direct contact with the electrode 112a. The support layer 104 may be located between the support layer 108 and the substrate 100. The dielectric layer 116 may be further located on the support layer 104 and the support layer 108. The semiconductor structure 10 may further include the stop layer 110. The stop layer 110 may be located between the support layer 104 and the substrate 100. The dielectric layer 116 may be further located on the stop layer 110.

In addition, details of each of the components in the semiconductor structure 10 (e.g., materials, configurations, formation methods, etc.) have been described in detail in the above embodiments, which will not be described in the following.

Based on the above embodiments, it may be seen that in the semiconductor structure 10 and the manufacturing method thereof, the dielectric layer 114a is located between the surface S1 of the electrode 112a and the electrode 122, and the dielectric layer 116 is located between the dielectric layer 114a and the electrode 122 and between the surface S2 of the electrode 112a and the electrode 122. That is, the dielectric layer 114a and the dielectric layer 116 are provided on the surface S1 of the electrode 112a. In this way, the capacitor 124 may be prevented from bending or collapsing, thereby improving the structural strength of the capacitor 124 and the reliability of the semiconductor structure 10. In addition, the dielectric layer 114a may balance the thickness of the capacitance dielectric layers (including the dielectric layer 114a and the dielectric layer 116) located on the surface S1 (e.g., the inner surface) of the electrode 112a and the surface S2 (e.g., the outer surface) of the electrode 112a. In addition, the dielectric layer 114a may improve step coverage capability of the capacitance dielectric layers (including the dielectric layer 114a and the dielectric layer 116) located on the surface S1 (e.g., the inner surface) of the electrode 112a.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A semiconductor structure, comprising:
a substrate; and
a capacitor located on the substrate and comprising:
a first electrode located on the substrate and having a first surface and a second surface opposite to each other;
a second electrode located on the first electrode;
a first dielectric layer located between the first surface of the first electrode and the second electrode; and
a second dielectric layer located between the first dielectric layer and the second electrode and between the second surface of the first electrode and the second electrode, wherein the second dielectric layer is located on opposite sides of the first electrode.

2. The semiconductor structure according to claim 1, wherein the first dielectric layer is not located between the second surface of the first electrode and the second dielectric layer.

3. The semiconductor structure according to claim 1, wherein a cross-sectional shape of the first electrode comprises a U-shape.

4. The semiconductor structure according to claim 1, wherein the first dielectric layer and the first electrode do not include a same metal element.

5. The semiconductor structure according to claim 1, wherein the first dielectric layer is in direct contact with the first surface of the first electrode.

6. The semiconductor structure according to claim 1, wherein the second dielectric layer is in direct contact with the second surface of the first electrode.

7. The semiconductor structure according to claim 1, wherein a material of the first dielectric layer comprises a high dielectric constant material.

8. The semiconductor structure according to claim 1, wherein a material of the first dielectric layer comprises hafnium oxide, zirconium oxide, niobium oxide, lanthanum oxide, or tantalum oxide.

9. The semiconductor structure according to claim 1, wherein a thickness of the second dielectric layer located on the first surface of the first electrode is less than a thickness of the second dielectric layer located on the second surface of the first electrode.

10. The semiconductor structure according to claim 1, wherein a material of the first dielectric layer comprises a material with a dielectric constant greater than 20.

11. The semiconductor structure according to claim 1, wherein a material of the first dielectric layer comprises a material with an energy gap greater than 8 electron volts.

12. The semiconductor structure according to claim 1, further comprising:
a first support layer located on the second surface of the first electrode; and
a second support layer located on the second surface of the first electrode, wherein the first support layer is located between the second support layer and the substrate.

13. The semiconductor structure according to claim 12, wherein the second dielectric layer is further located on the first support layer and the second support layer.

14. A manufacturing method of a semiconductor structure, comprising:
providing a substrate; and
forming a capacitor on the substrate, wherein the capacitor comprises:
a first electrode located on the substrate and having a first surface and a second surface opposite to each other;
a second electrode located on the first electrode;
a first dielectric layer located between the first surface and the second electrode; and
a second dielectric layer located between the first dielectric layer and the second electrode and between the second surface and the second electrode, wherein the second dielectric layer is located on opposite sides of the first electrode.

15. The manufacturing method of the semiconductor structure according to claim 14, wherein a method of forming the first electrode and the first dielectric layer comprises:
forming a stack structure on the substrate;
forming an opening in the stack structure;
forming an electrode material layer conformally on the stack structure and in the opening;
forming a dielectric material layer conformally on the electrode material layer; and
performing a patterning process on the dielectric material layer and the electrode material layer to form the first dielectric layer and the first electrode.

16. The manufacturing method of the semiconductor structure according to claim 15, wherein a method of forming the dielectric material layer comprises atomic layer deposition.

17. The manufacturing method of the semiconductor structure according to claim 15, wherein the stack structure comprises:
a third dielectric layer located on the substrate;
a first support layer located on the third dielectric layer;
a fourth dielectric layer located on the first support layer; and
a second support layer located on the fourth dielectric layer.

18. The manufacturing method of the semiconductor structure according to claim 17, further comprising:
removing a portion of the second support layer to expose a portion of the fourth dielectric layer;
removing the fourth dielectric layer to expose the first support layer;
removing a portion of the first support layer to expose a portion of the third dielectric layer; and
removing the third dielectric layer.

19. The manufacturing method of the semiconductor structure according to claim 18, wherein a method of forming the second dielectric layer comprises:
after removing the third dielectric layer, forming the second dielectric layer conformally on the first electrode, the first dielectric layer, the first support layer, and the second support layer.

20. The manufacturing method of the semiconductor structure according to claim 14, wherein a method of forming the second dielectric layer comprises atomic layer deposition or chemical vapor deposition.
